(19) United States
(12) Patent Application Publication
(10) Pub. No.: US 2026/0136568 A1
(43) Pub. Date: May 14, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Man-Yun Wu, Hsinchu (TW); Hsiao-Kuan Wei, Longtan Township (TW); Hsuan-Ming Huang, Hsinchu (TW)

(21) Appl. No.: 19/059,920

(22) Filed: Feb. 21, 2025

Related U.S. Application Data
(60) Provisional application No. 63/719,212, filed on Nov. 12, 2024.

(51) Int. Cl. H10D 1/68; H10D 1/00

(52) U.S. Cl. CPC H10D 1/68; H10D 1/043

(57) ABSTRACT

Semiconductor devices and methods of manufacture are presented in which a bottom metal is formed over a substrate and the bottom metal is treated to form a first oxygen-free zone. A first dielectric material is deposited over the bottom metal, and the first dielectric material is patterned to expose the bottom metal. A capacitor is formed within the first dielectric material.

### PRIORITY CLAIM AND CROSS-REFERENCE

This application claims the benefit of U.S. Provisional Application No. 63/719,212, filed on Nov. 12, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates formation of a bottom metal over a substrate, in accordance with some embodiments.

FIG. 2 illustrates placement of a first photoresist, in accordance with some embodiments.

FIG. 3 illustrates a patterning of the bottom metal, in accordance with some embodiments.

FIG. 4 illustrates a first treatment process, in accordance with some embodiments.

FIG. 5 illustrates deposition of a dielectric layer over the bottom metal, in accordance with some embodiments.

FIG. 6 illustrates planarization of the dielectric layer over the bottom metal, in accordance with some embodiments.

FIG. 7 illustrates placement of a second photoresist, in accordance with some embodiments.

FIG. 8 illustrates a patterning of the dielectric layer, in accordance with some embodiments.

FIGS. 9A-9B illustrate a formation of additional conductive vias and redistribution layers, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to a particular embodiment in which a treatment is utilized on a bottom metal in order to minimize overetching during formation of a three-dimensional metal-insulating-metal capacitor. The embodiments presented herein, however, are intended to be illustrative of the ideas presented, and are not intended to limit the embodiments to the precise structures discussed herein. The ideas presented may be implemented in a wide variety of structures and processes, and all such embodiments are fully intended to be included within the scope of the embodiments.

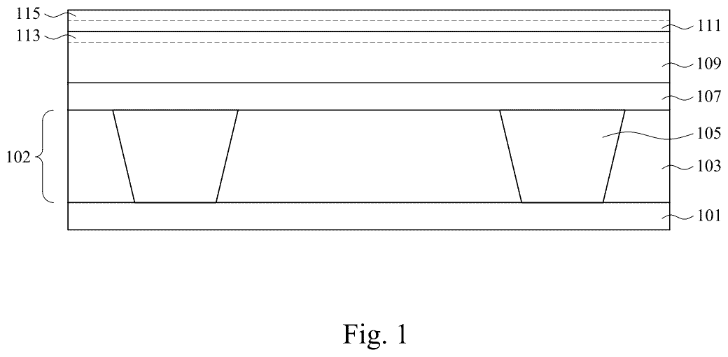

With reference now to FIG. 1, there is illustrated a beginning structure for the manufacture of the 3DMIM device including a substrate 101, a first dielectric layer 103, conductive features 105, a first etch stop layer 107, a second dielectric layer 109, and a bottom metal 111. The substrate 101 may be substantially conductive or semiconductive and may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates. Additionally, the substrate 101 at this point in the process may be part of a semiconductor wafer (the full wafer of which is not illustrated in FIG. 1) that will be singulated in a later step.

Active devices and other devices (not separately illustrated in FIG. 1) may be formed on and/or within the substrate 101. As one of skill in the art will recognize, a wide variety of active and passive devices such as capacitors, resistors, inductors and the like may be used to generate the desired structural and functional requirements of the design. The active devices may be formed using any suitable methods either within or else on the surface of the substrate 101.

Metallization layers 102 are formed over the substrate 101 and the active devices and are designed to connect the various active devices to form functional circuitry for the design. In an embodiment the metallization layers 102 are formed of layers of dielectric and conductive material (only one of which is illustrated in FIG. 1 for clarity) and may be formed through any suitable process (such as deposition, damascene, dual damascene, etc.).

In an embodiment the conductive material may be a material such as copper formed using, e.g., a damascene or dual damascene process, whereby an opening is formed within the dielectric material of the metallization layers 102, the opening is filled and/or overfilled with a conductive material such as copper, and a planarization process is performed to embed the conductive material within the dielectric material. However, any suitable material and any suitable process may be used to form the metallization layers 102.

As part of the metallization layers 102, a top metal layer is formed as a top most layer within the metallization layers 102. In an embodiment the top metal layer includes a first dielectric layer 103 and conductive features 105 formed within the first dielectric layer 103. The top metal layer may be formed by initially depositing the first dielectric layer 103 over a top surface of underlying layers of the metallization layers 102. The first dielectric layer 103 may be deposited by chemical vapor deposition (CVD), physical vapor deposition (PVD), or the like. However, any suitable material and method of deposition may be utilized.

Once the first dielectric layer 103 has been formed, the first dielectric layer 103 may then be etched to form openings exposing a top surface of the underlying layers (not separately illustrated) of the metallization layers 102. In an embodiment the first dielectric layer 103 may be etched using, e.g., a via first dual damascene process, whereby a first masking and etching process is utilized to pattern and etch a via pattern at least partially into the first dielectric layer 103. Once the via pattern is etched, a second masking and etching process is utilized to pattern and etch a trench pattern into the first dielectric layer 103, wherein the etching of the first dielectric layer 103 further extends the via pattern through the first dielectric layer 103 to expose the underlying layer.

However, while a via first dual damascene structure is described, this is intended to merely be illustrative and is not intended to be limiting upon the embodiments. Rather, any suitable process or processes may be utilized to form the via openings and trench openings of the top metal layer. For example, a trench first dual damascene process, or even multiple single damascene processes, may be utilized. All such processes are fully intended to be included within the scope of the embodiments.

Once the via openings and trench openings have been formed, the conductive features 105 may be formed by depositing conductive material in the via openings and the trench openings using, for example, a plating process. In an embodiment the conductive features 105 may include conductive trenches and conductive vias connecting the conductive trenches to underlying structures. In an embodiment the conductive material may be copper, a copper alloy, aluminum, an aluminum alloy, combinations of these, or the like. However, any suitable material and any suitable process of formation may be utilized.

Once the via openings and trench openings have been filled and/or overfilled by the conductive material, the conductive features 105 may be formed by removing excess material from outside of the via openings and the trench openings. In an embodiment the removal may be performed using a planarization process such as a chemical mechanical polishing (CMP) process. However, any suitable removal process may be utilized.

In another embodiment, instead of using a damascene or dual damascene process to form the conductive features 105 embedded within the dielectric layer, the conductive features 105 may comprise a material such as an aluminum copper alloy. In such an embodiment the conductive features 105 within the top metal layer may be formed by first blanket depositing the material (e.g., aluminum copper) using a deposition process such as physical vapor deposition, chemical vapor deposition, combinations of these, or the like. Once the material has been deposited, the material may be pattered into the desired shape using, e.g., a photolithographic masking and etching process.

Further, once the conductive features 105 have been formed into the desired shape, the first dielectric layer 103 may be deposited over the conductive features 105. In an embodiment the first dielectric layer 103 may be deposited as described above in order to cover the conductive features 105. Once covered, the first dielectric layer 103 may be planarized using, e.g., a chemical mechanical polishing process, in order to provide a planar surface for subsequent processing.

Once the conductive features 105 and the first dielectric layer 103 have been formed, a first etch stop layer 107 is formed over the top metal layer 105. In an embodiment the first etch stop layer 107 may be formed of silicon carbon nitride (SiCN), using plasma enhanced chemical vapor deposition (PECVD), although other materials such as SiN, SiCON, SiC, SiOC, silicon oxynitride (SiON), SiOx, other dielectrics, combinations thereof, or the like, and other techniques of forming the first etch stop layer 107, such as low pressure CVD (LPCVD), PVD, or the like, could be used. The first etch stop layer 107 may have a thickness of between about 5 Å and about 200 Å or between about 5 Å and about 50 Å.

Once the first etch stop layer 107 has been formed, a second dielectric layer 109 may be formed over the first etch stop layer 107. In an embodiment the second dielectric layer 109 may be a dielectric material such as silicon nitride, silicon oxide, silicon oxynitride, combinations of these, or the like, deposited using a method such as chemical vapor deposition, atomic layer deposition, physical vapor deposition, combinations of these, or the like. However, any suitable material and deposition process may be utilized.

Additionally, once the second dielectric layer 109 has been formed, the second dielectric layer 109 may be exposed to the ambient environment as the second dielectric layer 109 is moved from one machine to another for further processing. During such an exposure, a native oxide (represented by the dashed box labeled 113 in FIG. 1) may form along a top surface of the second dielectric layer 109. The first native oxide 113 can occur when oxygen located within the ambient either directly reacts with the material of the second dielectric layer 109 to form, e.g., silicon oxynitride, or else the oxygen diffuses into the top surface of the second dielectric layer 109.

Once the second dielectric layer 109 has been formed, a bottom metal 111 is deposited over the second dielectric layer 109. In an embodiment the bottom metal 111 is formed from a conductive material such as titanium nitride or the like, using a deposition process such as chemical vapor deposition, atomic layer deposition, physical vapor deposition, combinations of these, or the like. The bottom metal 111 may be deposited to a thickness of about 600 Å. However, any suitable material, deposition process, and thickness may be utilized.

Additionally, once the bottom metal 111 has been formed, the bottom metal 111 may also be exposed to the ambient environment as the bottom metal 111 is moved from one machine to another for further processing. During such an exposure, a second native oxide (represented by the dashed box labeled 115 in FIG. 1) may form along a top surface of the bottom metal 111. The second native oxide 115 can occur when oxygen located within the ambient either directly reacts with the material of the bottom metal 111 109 to form, e.g., titanium oxynitride, or else the oxygen diffuses into the top surface of the bottom metal 111.

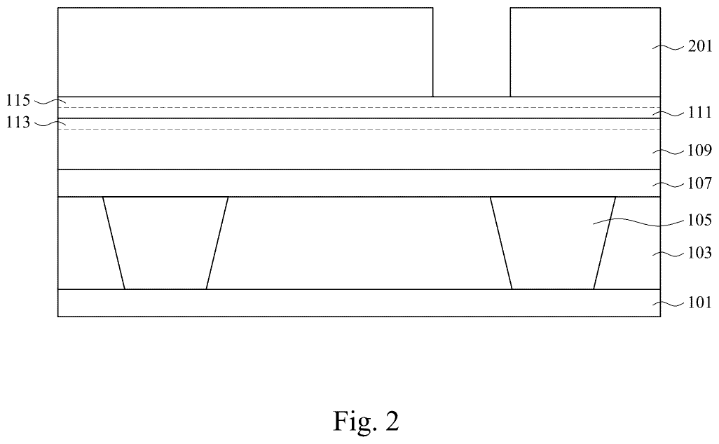

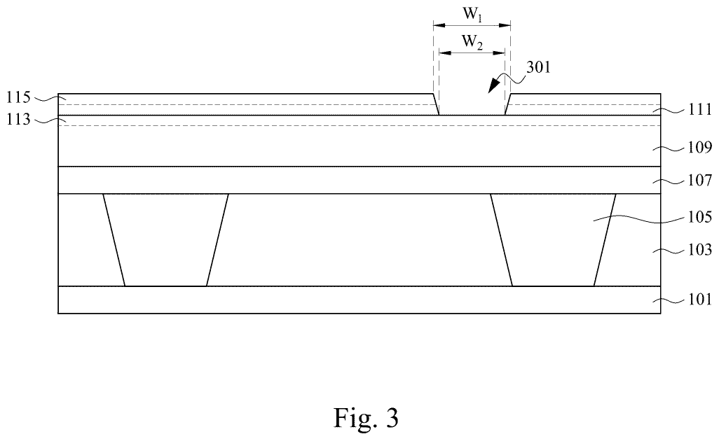

FIG. 2 illustrates a placement and patterning of a first photoresist 201 that will be used to help pattern a first opening 301 (not illustrated in FIG. 2 but illustrated and described further below with respect to FIG. 3) into the bottom metal 111. In an embodiment the first photoresist 201 comprises one or more layers of material, wherein at least one of the one or more materials is a photosensitive material. The individual materials may be deposited using any suitable means, such as chemical vapor deposition, spin-on processes, or the like.

Once the first photoresist 201 has been placed over the bottom metal 111, the first photoresist 201 may be patterned. In an embodiment the patterning may be performed by exposing a portion of the photosensitive material to a patterned energy source (e.g., light) in order to chemically react and change the solubility of a portion of the photosensitive material. Once exposed, the photosensitive material can be developed using one or more solvents in order to remove either the exposed or unexposed portions of the photosensitive material, which is then used as a mask in order to etch through any other remaining layers of the first photoresist 201.

FIG. 3 illustrates that once the first photoresist 201 has been placed and patterned, the first photoresist 201 may be utilized to pattern the underlying bottom metal 111 and form a first opening 301. In an embodiment the patterning may be performed using a directional etching process, such as a reactive ion etching process, in order to transfer the pattern of the first photoresist 201 to the underlying bottom metal 111. However, any suitable etching process may be utilized.

In an embodiment the first opening 301 may be formed to extend all of the way through the bottom metal 111 and to expose a portion of, but not all of, the second dielectric layer 109. For example, the first opening 301 may be formed to extend through the second native oxide 115 as well as the remainder of the bottom metal 111. Additionally, if desired, the first opening 301 may be formed to extend partially into the second dielectric layer 109.

Additionally, the first opening 301 can be formed to have sloping sidewalls such that the first opening 301 has a first width W₁ at a top of the first opening 301 and a second width W₂ smaller than the first width W₁ at a bottom of the first opening 301. Any suitable dimensions may be utilized.

Of course, the description of the first opening 301 having sloped sidewalls is intended to be illustrative and is not intended to limit the embodiments presented. In other embodiments the first opening 301 may have sidewalls that are perpendicular to the substrate 101, or any other suitable configuration. All such configurations are fully intended to be included within the scope of the embodiments.

Once the bottom metal 111 has been patterned to form the first opening 301, the first photoresist 201 is removed. For example, if the etching process used to pattern the bottom metal 111 does not fully remove the first photoresist 201 during the etching process, one or more ashing, etching and rinsing processes may be used to remove the one or more layers of the first photoresist 201. Any suitable process may be utilized.

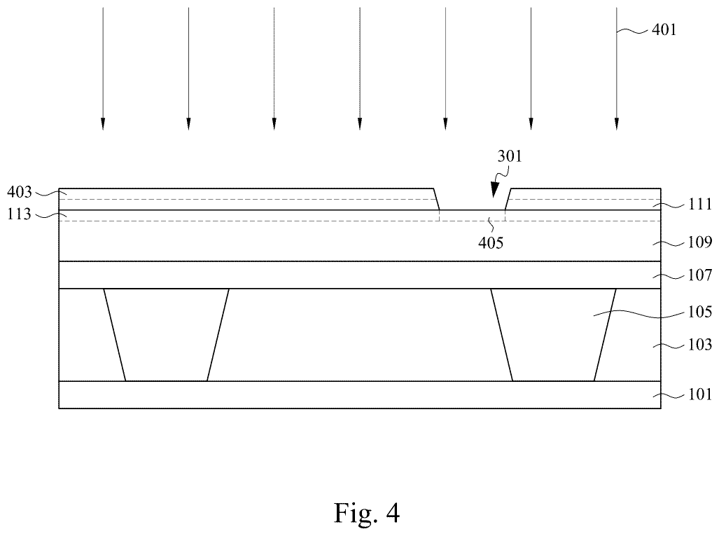

FIG. 4 illustrates a treatment process (represented in FIG. 4 by the arrows labeled 401) that may be used to remove the second native oxide 115 from the top surface of the bottom metal 111 and form a first oxygen-free zone 403 along a top surface of the bottom metal 111. In an embodiment the first treatment process 401 may be a plasma treatment process using one or more plasmas created from precursor materials that can be used to remove the oxygen from the second native oxide 155 of the bottom metal 111. In a particular embodiment the one or more plasmas can be created using a precursor such as nitrogen (N₂) or the like. However, any suitable precursors may be utilized.

The first treatment process 401 may be initiated by placing the desired precursor gases into a plasma generator and igniting the desired precursor gases into the plasma. In an embodiment the plasma generator may be a transformer coupled plasma generator located within a same treatment chamber that the bottom metal 111 is placed. However, any other suitable method of generating the plasma, such as using inductively coupled plasma systems, magnetically enhanced reactive ion etching, electron cyclotron resonance, a remote plasma generator, or the like, may also be utilized. All such methods are fully intended to be included within the scope of the embodiments.

Once ignition has occurred and the desired plasma has been generated, the first treatment process 401 may be utilized to treat the exposed surfaces of the bottom metal 111. During the process, any suitable process parameters and time periods may be utilized.

Additionally, while a specific embodiment of the plasma process 401 has been described above with respect to FIG. 4, these discussions are intended to be illustrative only and are not intended to be limiting upon the embodiments. Rather, any suitable combination of precursors and process conditions may be utilized. All such combinations are fully intended to be included within the scope of the embodiments.

By performing the first treatment process 401 as described above, the first oxygen-free zone 403 may be formed along the top surface and sidewalls of the bottom metal 111. For example, in an embodiment in which the bottom metal 111 is titanium nitride, the first treatment process 401 causes the titanium oxide and oxygen within the second native oxide 115 to be removed. As such, the first oxygen-free zone 403 (or at least mostly oxygen free) can be created along the top surface and sidewalls of the bottom metal 111.

Additionally, while the first treatment process 401 may be used to remove oxygen from the bottom metal 111 and create the first oxygen-free zone 403, the first treatment process 401 will also remove oxygen from each other surface exposed during the first treatment process 401, such as the portion of the second dielectric layer 109 expose by the first opening 301. As such, by removing oxygen from the exposed surface of the second dielectric layer 109, a second oxygen-free zone 405 (or at least mostly oxygen free) may be formed along the exposed surface of the second dielectric layer 109.

However, the formation of the second oxygen-free zone 405 does not affect those portions of the first native oxide 113 that are covered by the bottom metal 111. As such, the top surface of the second dielectric layer 109 comprises both the first native oxide 113 and also comprises the second oxygen-free zone 405, wherein the second oxygen-free zone 405 is bracketed by the first native oxide 113 on opposite sides. Any suitable combination of the first native oxide 113 and the second oxygen-free zone 405 may be used.

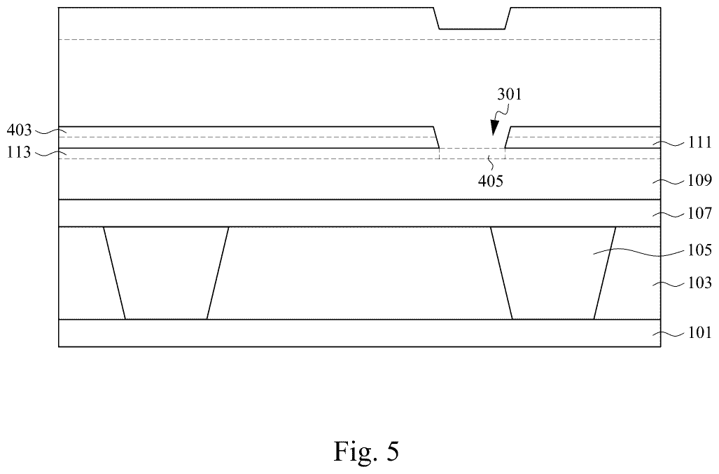

FIG. 5 illustrates deposition of a third dielectric layer 501 over the bottom metal 111 and into the first opening 301. In an embodiment the third dielectric layer 501 may be a dielectric material such as silicon nitride, silicon oxide, silicon oxynitride, combinations of these, or the like, deposited using a method such as chemical vapor deposition, atomic layer deposition, physical vapor deposition, combinations of these, or the like. However, any suitable material and deposition process may be utilized.

Additionally, in some embodiments the process proceeds from the first treatment process 401 to or through the deposition of the third dielectric layer 501, the processes may be performed in-situ with no vacuum breaks. For example, the processes may be performed in a single chamber or multiple chambers within a vacuumed mainframe. In other embodiments, the processes may be performed in separate chambers, either with or without vacuum breaks. Any suitable combination of processes may be utilized.

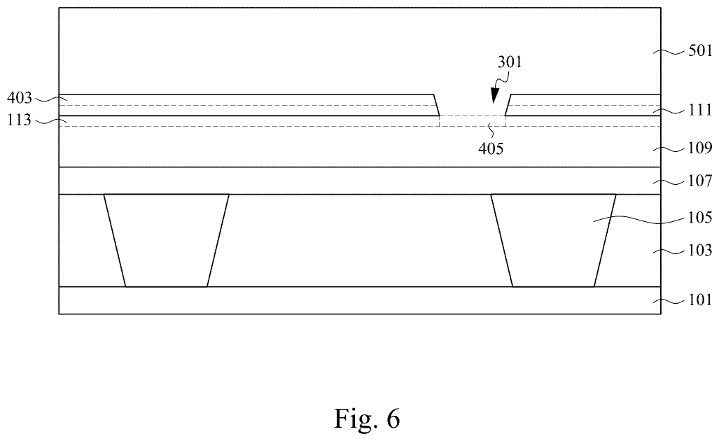

FIG. 6 illustrates that, once the third dielectric layer 501 has been deposited, the third dielectric layer 501 may be planarized in order to provide a planar surface for subsequent manufacturing processes. In an embodiment the planarization may be a chemical mechanical planarization process which uses etchants and particles along with a polishing platen in order to planarize the top surface. However, any other planarization process, such as a grinding process or even a series of one or more etches, may be utilized to planarize the top surface of the third dielectric layer 501.

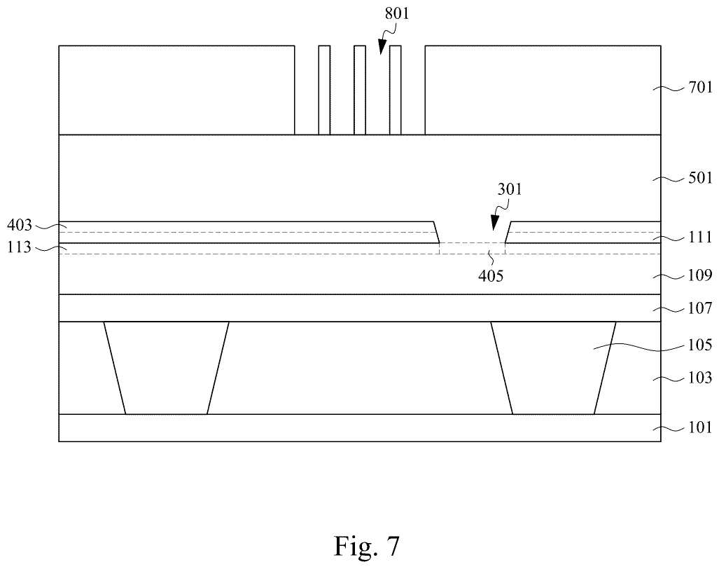

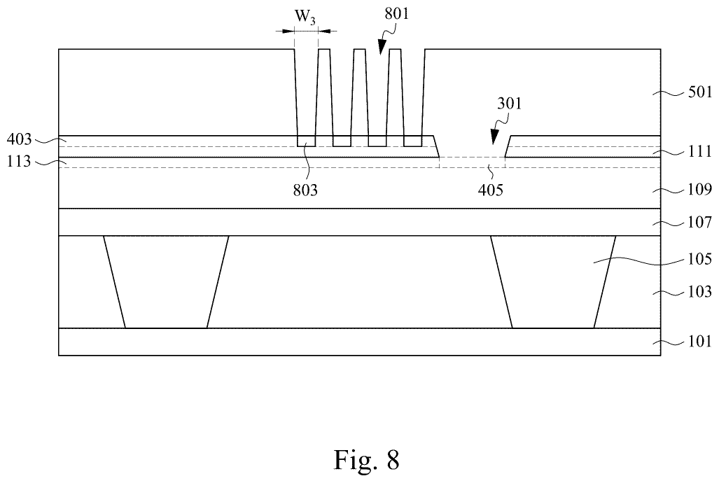

FIG. 7 illustrates a placement and patterning of a second photoresist 701 over the third dielectric layer 501 that will be used to help pattern second openings 801 (not illustrated in FIG. 7 but illustrated and described further below with respect to FIG. 8) into the third dielectric layer 501. In an embodiment the second photoresist 701 comprises one or more layers of material, wherein at least one of the one or more layers of material is a photosensitive material. The individual materials may be deposited using any suitable means, such as chemical vapor deposition, spin-on processes, or the like.

Once the second photoresist 701 has been placed, the second photoresist 701 may be patterned. In an embodiment the patterning may be performed by exposing a portion of the photosensitive material to a patterned energy source (e.g., light) in order to chemically react and change the solubility of a portion of the photosensitive material. Once exposed, the photosensitive material can be developed using one or more solvents in order to remove either the exposed or unexposed portions of the photosensitive material, which is then used as a mask in order to etch through any other remaining layers of the second photoresist 701.

FIG. 8 illustrates that once the second photoresist 701 has been placed and patterned, the second photoresist 701 may be utilized to pattern the underlying third dielectric layer 501 and form multiple ones of the second openings 801. In an embodiment the patterning may be performed using a directional etching process, such as a reactive ion etching process, in order to transfer the pattern of the second photoresist 701 to the underlying third dielectric layer 501. However, any suitable etching process may be utilized.

In an embodiment the second openings 801 may comprise four openings and be formed to extend all of the way through the third dielectric layer 501 and to expose the bottom metal 111. For example, the second openings 801 may be formed to expose the first oxygen-free region 403 located along the top surface of the bottom metal 111. However, any suitable number of the second openings 801 and any suitable configuration of the second openings 801 may be utilized.

Additionally, the second openings 801 can be formed to have dimensions that are suitable for the formation of metal-insulator-metal (MIM) capacitors within the second openings 801. As such, in some embodiments the second openings 801 may be formed to have a third width W₃ less than the second width W₂. However, any suitable dimensions may be utilized.

Once the third dielectric layer 501 has been patterned to form the second openings 801, the second photoresist 701 is removed. For example, if the etching process used to pattern the third dielectric layer 501 does not fully remove the second photoresist 701 during the etching process, once or more ashing, etching and rinsing processes may be used to remove the one or more layers of the second photoresist 701. Any suitable process may be utilized.

However, by removing the oxygen from the bottom metal 111 prior to the patterning of the third dielectric layer 501, the oxygen is simply not present and not available to react with the other chemicals present during the patterning of the third dielectric layer 501. As such, problems associated with this presence of oxygen, such as an increased lateral etch rate along a bottom of the second openings 801, can be reduced and/or eliminated. As such, problems related to an over-etching profile can be mitigated, and the sidewalls of the second openings 801 can be more straight, especially along a bottom of the second openings 801, than otherwise achievable.

Additionally, once the second openings 801 have been formed and portions of the first oxygen-free zone 403 have been exposed, the first oxygen-free zone 403 (which is now exposed by the second openings 801 and is not covered by the third dielectric layer 501) may also be exposed to the ambient environment as the substrate 101 is moved from one machine to another for additional processing. During such an exposure, a third native oxide (represented by the boxes labeled 803 in FIG. 8) may form along portions of the top surface of the bottom metal 111. The third native oxide 803 can occur when oxygen located within the ambient either directly reacts with the material of the bottom metal 111 to form, e.g., titanium oxynitride, or else the oxygen diffuses into the top surface of the bottom metal 111.

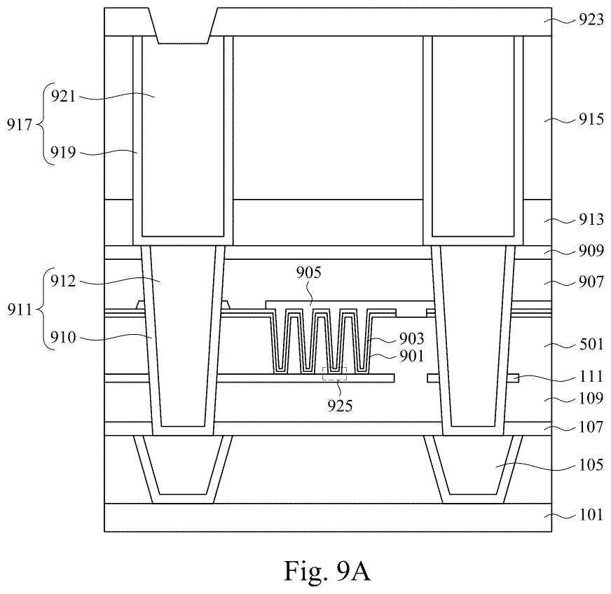

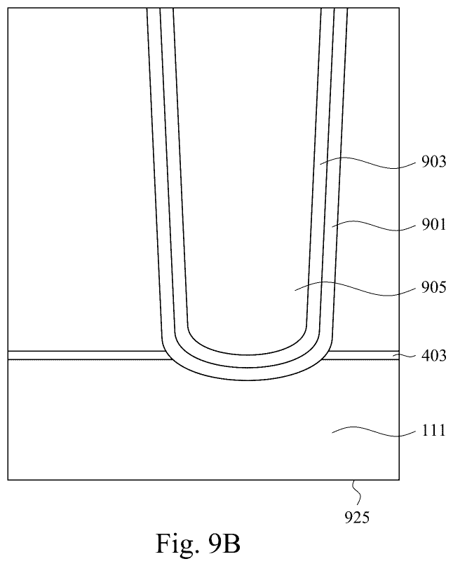

FIG. 9A illustrates formation of a bottom capacitor plate 901, a capacitor dielectric 903, and a top capacitor plate 905 extending through the third dielectric layer 501 and within the second openings 801. Looking first at the bottom capacitor plate 901, the bottom capacitor plate 901 may be formed by depositing and patterning a layer of conductive material, such as TiN, TaN, ruthenium, or the like. The bottom capacitor plates 901 may be formed, for example, by CVD or ALD techniques and may be between about 100 Å to about 500 Å in thickness. However, any suitable materials and processes may be utilized.

Once the bottom capacitor plates 901 have been deposited, the bottom capacitor plates 901 may be patterned into the desired shape. In an embodiment the bottom capacitor plates 901 may be patterned using one or more photolithographic masking and etching processes. However, any suitable process may be used.

Once the bottom capacitor plate 901 has been formed and patterned, the capacitor dielectric 903 may be deposited. In an embodiment the capacitor dielectric 903 may be formed over the bottom capacitor plates 901 to electrically isolate the bottom capacitor plates 901 from the top capacitor plates 905. In an embodiment the capacitor dielectric 903 may be one or more layers of high-k dielectric materials, such as zirconium oxide, aluminum oxide, hafnium oxide, combinations of these, or the like, deposited using a deposition process such as atomic layer deposition, chemical vapor deposition, combinations of these, or the like. However, any suitable materials and suitable method of deposition may be utilized.

Once the capacitor dielectric 903 has been formed, the top capacitor plate 905 can be formed in order to form the capacitor 906. In an embodiment the top capacitor plate 905 may be formed using similar materials and methods as the bottom capacitor plate 901. For example, the top capacitor plate 905 may be formed by depositing and patterning a layer of conductive material, such as TiN, TaN, ruthenium, or the like, using a deposition process such as, for example, CVD or ALD techniques, and may be between about 100 Å to about 500 Å in thickness. However, any suitable materials and processes may be utilized.

Once the top capacitor plate 905 has been formed, the top capacitor plate 905 may be patterned to form the desired capacitors 906. In an embodiment the top capacitor plate 905 may be patterned using, e.g., a suitable photolithographic masking and etching process in which a photoresist (not shown in FIG. 8) is formed over the top capacitor plate 905, irradiated, and developed so that underlying portions of the top capacitor plates 905 are exposed. Once the photoresist has been developed, the exposed top capacitor plates 905 and any desired underlying layer may be removed using a suitable etching process with the photoresist as a mask.

Once the top capacitor plate 905 has been formed and patterned, a fourth dielectric layer 907 is formed over the top capacitor plate 905. In an embodiment the fourth dielectric layer 907 may be a dielectric material such as silicon nitride, silicon oxide, silicon oxynitride, combinations of these, or the like, deposited using a method such as chemical vapor deposition, atomic layer deposition, physical vapor deposition, combinations of these, or the like. However, any suitable material and deposition process may be utilized.

A second etch stop layer 909 is formed over the fourth dielectric layer 907. In an embodiment the second etch stop layer 909 may be formed of SiOx, using plasma enhanced chemical vapor deposition (PECVD), although other materials such as SiN, SiCON, SiC, SiOC, silicon oxynitride (SiON), SiCN, other dielectrics, combinations thereof, or the like, and other techniques of forming the second etch stop layer 909, such as low pressure CVD (LPCVD), PVD, or the like, could be used. The second etch stop layer 909 may have a thickness of between about 5 Å and about 200 Å. However, any suitable materials, processes, and thicknesses may be used.

FIG. 9A additionally illustrated the formation of redistribution vias 911 that extend to make physical and electrical connection with the top metal layer. In an embodiment the formation of the redistribution vias 911 may be initiated by initially forming via openings (not separately labeled in FIG. 9A) that extends through the second etch stop layer 909, the fourth dielectric layer 907, the third dielectric layer 501, the bottom metal 111, the second dielectric layer 109, and the first etch stop layer 107 to expose the top metal layer. The via openings may be formed using one or more photolithographic masking and etching processes. However, any suitable methods may be utilized.

Once the via openings have been formed, the redistribution vias 911 may be formed within the via openings. In an embodiment the redistribution vias 911 may comprise a first barrier layer 910 and a first conductive fill material 912. The first barrier layer 910 may be a material such as titanium, titanium nitride, tantalum, tantalum nitride, combinations of these, or the like, using a deposition process such as atomic layer deposition, chemical vapor deposition, physical vapor deposition, combinations of these, or the like. However, any suitable materials and method of manufacture may be utilized.

The first conductive fill material 912 may comprise copper, although other suitable materials such as aluminum, alloys, doped polysilicon, combinations thereof, and the like, may alternatively be utilized. The conductive fill material may be formed by initially depositing a seed layer (not shown) and then electroplating copper onto the seed layer, filling and overfilling the via openings. Once the via openings have been filled, excess portions of the first barrier layer 910, seed layer, and first conductive fill material 912 outside of the via openings may be removed through a planarization process such as chemical mechanical polishing (CMP), although any suitable removal process may be used.

FIG. 9A additionally illustrates formation of a fifth dielectric layer 913. In an embodiment the fifth dielectric layer 913 may be a dielectric material such as silicon nitride, silicon oxide, silicon oxynitride, combinations of these, or the like, deposited using a method such as chemical vapor deposition, atomic layer deposition, physical vapor deposition, combinations of these, or the like. However, any suitable material and deposition process may be utilized.

Once the fifth dielectric layer 913 has been formed, a sixth dielectric layer 915 may be formed over the fifth dielectric layer 913. In an embodiment the sixth dielectric layer 915 may be a dielectric material such as undoped silicate glass (USG), silicon nitride, silicon oxide, silicon oxynitride, combinations of these, or the like, deposited using a method such as spin-on, chemical vapor deposition, atomic layer deposition, physical vapor deposition, combinations of these, or the like. However, any suitable material and deposition process may be utilized.

Once the sixth dielectric layer 915 has been formed, a first redistribution layer 917 may be formed to provide electrical routing. In an embodiment the first redistribution layer 917 may be initiated by initially forming RDL openings (not separately labeled in FIG. 9A) that extends through the sixth dielectric layer 915 and the fifth dielectric layer 913 to expose the redistribution vias 911. The RDL openings may be formed using one or more photolithographic masking and etching processes. However, any suitable methods may be utilized.

Once the RDL openings have been formed, the first redistribution layer 917 may be formed within the RDL openings. In an embodiment the first redistribution layer 917 may comprise a second barrier layer 919 and a second conductive fill material 921. The second barrier layer 919 may be a material such as titanium, titanium nitride, tantalum, tantalum nitride, combinations of these, or the like, using a deposition process such as atomic layer deposition, chemical vapor deposition, physical vapor deposition, combinations of these, or the like. However, any suitable materials and method of manufacture may be utilized.

The second conductive fill material 921 may comprise copper, although other suitable materials such as aluminum, alloys, doped polysilicon, combinations thereof, and the like, may alternatively be utilized. The second conductive fill material 921 may be formed by initially depositing a seed layer (not shown) and then electroplating copper onto the seed layer, filling and overfilling the via openings. Once the RDL openings have been filled, excess portions of the second barrier layer 919, the seed layer, and the second conductive fill material 921 outside of the RDL openings may be removed through a planarization process such as chemical mechanical polishing (CMP), although any suitable removal process may be used.

Once the first redistribution layer 917 has been formed, a first passivation layer 923 may be placed and patterned over the first redistribution layer 917. In an embodiment the first passivation layer 923 may comprise a dielectric material (e.g., silicon oxide, silicon nitride, silicon oxynitride, or the like), a polymer material (e.g., a polyimide, polybenzoxazole (PBO), polyimide, a benzocyclobuten (BCB) based polymer, or the like), or combinations thereof, or the like. The first passivation layer 923 may be formed by a deposition process, such as by CVD, PVD, ALD, spin-on, combinations of these, or the like.

Once the first passivation layer 923 has been deposited, the first passivation layer 923 may be patterned in order to expose a portion of the first redistribution layer 917. In an embodiment the first passivation layer 923 may be patterned using one or more photolithographic masking and etching processes. However, any suitable process may be utilized.

Once the first passivation layer 923 has been deposited and patterned, additional processing (not separately illustrated in the figures) may be performed. For example, external connectors such as solder bumps or copper pillars may be formed, the substrate 101 may be singulated, and the overall device may be connected to other devices in order to provide a desired functionality. All such steps are fully intended to be included within the scope of the embodiments presented herein.

FIG. 9B illustrates a close-up view of the box labeled 925 in FIG. 9A. In this figure there is illustrated the first oxygen-free zone 403 along a top surface of the bottom metal 111, along with the bottom capacitor plates 901 slightly extending into the bottom metal 111 (where the third native oxide 803 is not separately illustrated). As can be seen, when the bottom capacitor plates 901 is formed, the bottom capacitor plates 901 may be formed to have a rounded bottom surface that is in physical contact with the bottom metal 111. However, any suitable shape may be utilized.

By removing the oxygen from the bottom metal 111 prior to the patterning of the third dielectric layer 501, the defects created by over etching during the patterning can be reduced or eliminated. As such, gap fill issues may also be reduced, and the overall critical dimensions of the second openings 801 (and the subsequently formed capacitors) can be enlarged from 60-70 Å to about 80-95 Å.

In accordance with an embodiment, a method of manufacturing a semiconductor device includes: forming a bottom metal over a substrate; treating the bottom metal to remove oxygen and form a first oxygen-free zone; depositing a first dielectric material over the bottom metal; patterning the first dielectric material to expose the bottom metal; and forming a capacitor within the first dielectric material. In an embodiment, the treating the bottom metal also treats a portion of a second dielectric material, the second dielectric material underlying the bottom metal. In an embodiment, the method further includes oxidizing a top surface of the second dielectric material prior to the forming the bottom metal. In an embodiment, the second dielectric material comprises silicon nitride. In an embodiment, the forming the bottom metal comprises forming titanium nitride. In an embodiment the method further includes oxidizing a portion of the bottom metal after the patterning the first dielectric material. In an embodiment, the patterning the first dielectric material forms multiples openings that expose the bottom metal.

In accordance with another embodiment, a method of manufacturing a semiconductor device includes: depositing a first dielectric layer over a substrate; oxidizing a top surface of the first dielectric layer to form a first oxidized region; depositing a bottom metal over the top surface of the first dielectric layer; oxidizing a top surface of the bottom metal to form a second oxidized region; patterning the bottom metal to expose a portion of the first oxidized region; treating all of the second oxidized region and a portion of the first oxidized region to remove oxygen; depositing a second dielectric layer over the bottom metal; and forming a capacitor through the second dielectric layer and in electrical contact with the bottom metal. In an embodiment the method further includes re-oxidizing the top surface of the bottom metal after the depositing the second dielectric layer. In an embodiment the treating is performed at least in part by exposing the second oxidized region with a plasma. In an embodiment the plasma is a nitrogen plasma. In an embodiment the bottom metal comprises titanium nitride. In an embodiment the first dielectric layer comprises silicon nitride. In an embodiment the forming the capacitor forms a metal-insulator-metal capacitor.

In accordance with yet another embodiment, a semiconductor device includes: a first dielectric layer over a substrate, the first dielectric layer having a first top surface, the first top surface including: a first oxidized portion; and a first oxygen-free portion; a bottom metal over the first oxidized portion, the bottom metal having a second top surface, the second top surface including: a second oxidized portion; and a second oxygen-free portion; and a capacitor located over the second oxidized portion. In an embodiment the bottom metal comprises titanium nitride. In an embodiment the first dielectric layer comprises silicon oxide. In an embodiment the capacitor makes physical contact with the second oxidized portion at multiple places. In an embodiment the capacitor is a metal-insulator-metal capacitor. In an embodiment the semiconductor device further includes a second dielectric layer surrounding the capacitor, the second dielectric layer comprising silicon nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming a bottom metal over a substrate;
treating the bottom metal to remove oxygen and form a first oxygen-free zone;
depositing a first dielectric material over the bottom metal;
patterning the first dielectric material to expose the bottom metal; and
forming a capacitor within the first dielectric material.

2. The method of claim 1, wherein the treating the bottom metal also treats a portion of a second dielectric material, the second dielectric material underlying the bottom metal.

3. The method of claim 2, further comprising oxidizing a top surface of the second dielectric material prior to the forming the bottom metal.

4. The method of claim 3, wherein the second dielectric material comprises silicon nitride.

5. The method of claim 1, wherein the forming the bottom metal comprises forming titanium nitride.

6. The method of claim 1, further comprising oxidizing a portion of the bottom metal after the patterning the first dielectric material.

7. The method of claim 1, wherein the patterning the first dielectric material forms multiples openings that expose the bottom metal.

8. A method of manufacturing a semiconductor device, the method comprising:
depositing a first dielectric layer over a substrate;
oxidizing a top surface of the first dielectric layer to form a first oxidized region;
depositing a bottom metal over the top surface of the first dielectric layer;
oxidizing a top surface of the bottom metal to form a second oxidized region;
patterning the bottom metal to expose a portion of the first oxidized region;
treating all of the second oxidized region and a portion of the first oxidized region to remove oxygen;
depositing a second dielectric layer over the bottom metal; and
forming a capacitor through the second dielectric layer and in electrical contact with the bottom metal.

9. The method of claim 8, further comprising re-oxidizing the top surface of the bottom metal after the depositing the second dielectric layer.

10. The method of claim 8, wherein the treating is performed at least in part by exposing the second oxidized region with a plasma.

11. The method of claim 10, wherein the plasma is a nitrogen plasma.

12. The method of claim 8, wherein the bottom metal comprises titanium nitride.

13. The method of claim 12, wherein the first dielectric layer comprises silicon nitride.

14. The method of claim 8, wherein the forming the capacitor forms a metal-insulator-metal capacitor.

15. A semiconductor device comprising:
a first dielectric layer over a substrate, the first dielectric layer having a first top surface, the first top surface comprising:
a first oxidized portion; and
a first oxygen-free portion;
a bottom metal over the first oxidized portion, the bottom metal having a second top surface, the second top surface comprising:
a second oxidized portion; and
a second oxygen-free portion; and
a capacitor located over the second oxidized portion.

16. The semiconductor device of claim 15, wherein the bottom metal comprises titanium nitride.

17. The semiconductor device of claim 16, wherein the first dielectric layer comprises silicon oxide.

18. The semiconductor device of claim 15, wherein the capacitor makes physical contact with the second oxidized portion at multiple places.

19. The semiconductor device of claim 15, wherein the capacitor is a metal-insulator-metal capacitor.

20. The semiconductor device of claim 15, further comprising a second dielectric layer surrounding the capacitor, the second dielectric layer comprising silicon nitride.
